(19) United States
(12) Patent Application Publication
(10) Pub. No.: US 2008/0205469 A1
(43) Pub. Date: Aug. 28, 2008

(54) OPTICAL ELEMENT

(75) Inventors: Yasutaka IMAI, Suwa-shi (JP); Tetsuo NISHIDA, Suwa-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/033,373

(22) Filed: Feb. 19, 2008

(30) Foreign Application Priority Data
Feb. 22, 2007 (JP) 2007-042218

(51) Int. Cl. H01S 5/06

(52) U.S. Cl. 372/50.21

(57) ABSTRACT

An optical element includes: a surface emitting semiconductor laser portion; a separator formed superjacent to the surface emitting semiconductor laser portion; and a light detector formed superjacent to the separator. The separator electrically separates the surface emitting semiconductor laser portion and the light detector and has a first separation layer made of a first conductive type semiconductor and a second separation layer that is formed one of superjacent to and lower the first separation layer and is made of a second conductive type semiconductor having a refractive index different from a refractive index of the first separation layer. The separator functions as a mirror that reflects at least a part of light having an oscillation wavelength generated from the surface emitting semiconductor laser portion at an interface between the first separation layer and the second separation layer.

The entire disclosure of Japanese Patent Application No. 2007-042218, filed Feb. 22, 2007 is expressly incorporated by reference herein.

### BACKGROUND

1. Technical Field

The present invention relates to an optical element.

2. Related Art

Surface emitting semiconductor lasers have a characteristic of the light output varying by surrounding temperature. Because of this characteristic, some optical modules using surface emitting semiconductor lasers have a light detection function to monitor a light output value by detecting part of a laser beam emitted from the surface emitting semiconductor lasers. For example, a light detection element, such as a photo diode, is disposed on a surface emitting semiconductor laser to monitor part of a laser beam emitted from the surface emitting semiconductor lasers in an element (refer to JP-A-10-135568).

### SUMMARY

An advantage of the invention is to improve reliability of an optical element including a surface emitting semiconductor laser and a light detector.

According to a first aspect of the invention, an optical element includes: a surface emitting semiconductor laser portion; a separator formed superjacent to the surface emitting semiconductor laser portion; and a light detector formed superjacent to the separator. The separator electrically separates the surface emitting semiconductor laser portion and the light detector and has a first separation layer made of a first conductive type semiconductor and a second separation layer that is formed superjacent to or under the first separation layer and is made of a second conductive type semiconductor having a refractive index different from a refractive index of the first separation layer. The separator functions as a mirror that reflects at least a part of light having an oscillation wavelength generated from the surface emitting semiconductor laser portion at an interface between the first separation layer and the second separation layer.

In the optical element, a plurality of potential barriers exists against carriers (electrons or holes) between the first contact layer and the second mirror. Thus, a leak current between the surface emitting semiconductor laser portion and the light detector can be reduced. As a result, the reliability of the optical element can be improved. The separator also functioning as a mirror allows the mirror of the surface emitting semiconductor laser portion to be formed thin. As a result, a low-resistance structure can be achieved.

In the description according to the invention, the term “superjacent” is used in phrases such as “forming a specific thing (hereafter referred to as “A”) superjacent to another specific thing (hereafter referred to as “B”). The phrase in this example includes both cases of forming B directly on A, as well as forming B over A with another thing interposed therebetween.

In the optical element, the separator may include the first separation layer and the second separation layer in a plurality of numbers and the first separation layer and the second separation layer may be layered alternately.

In the optical element, the surface emitting semiconductor laser portion may include a first mirror, an active layer formed superjacent to the first mirror, and a second mirror formed superjacent to the active layer. A refractive index of an uppermost layer of the second mirror may be different from a refractive index of a lowest layer of the separator.

In the optical element, the surface emitting semiconductor laser portion may include a first mirror, an active layer formed superjacent to the first mirror, and a second mirror formed superjacent to the active layer. The second mirror may be a layered body in which a first refractive index layer having a first refractive index and a second refractive index layer having a second refractive index are alternately layered. The number of layers composed of the first separation layer and the second separation layer in the separator may be larger than the number of layers composed of the first refractive index layer and the second refractive index layer.

In the optical element, the separator may be a semiconductor mirror made of a first conductive type AlₓGa₁₋ₓAs layer and a second conductive type Al_{y}Ga_{1-y}As layer that are alternately layered, and x may be different from y.

In the optical element, the separator may be a semiconductor mirror made of a p-type AlₓGa₁₋ₓAs layer and an n-type Al_{y}Ga_{1-y}As layer that are alternately layered, and x may be larger than y.

In the optical element, the first conductive type AlₓGa₁₋ₓAs layer may be formed as a lowest layer in the separator, and an uppermost layer of the second mirror may be made of a first conductive type AlₓGa_{1-z}As layer or a second conductive type Al_{z}Ga_{1-z}As layer, and z may be smaller than x.

In the optical element, the surface emitting semiconductor laser portion may include a first mirror, an active layer formed superjacent to the first mirror, a second mirror formed superjacent to the active layer, a first electrode electrically coupled with the first mirror, and a second electrode electrically coupled with the second mirror. The light detector may include a first contact layer formed superjacent to the separator, a light absorption layer formed superjacent to the first contact layer, a second contact layer formed superjacent to the light absorption layer, a third electrode electrically coupled with the first contact layer, and a fourth electrode electrically coupled with the second contact layer. The first electrode, the second electrode, the third electrode, and the fourth electrode may be electrically independent from each other.

According to a second aspect of the invention, an optical element includes: a light detector; a separator formed superjacent to the light detector; and a surface emitting semiconductor laser portion formed superjacent to the separator. The surface emitting semiconductor laser portion emits laser light upwardly and oscillates light in a downward direction. The light detector detects the light oscillated from the surface emitting semiconductor laser portion. The separator electrically separates the surface emitting semiconductor laser portion and the light detector and has a first separation layer made of a first conductive type semiconductor and a second separation layer that is formed superjacent to or under the first separation layer and is made of a second conductive type semiconductor having a refractive index different from a refractive index of the first separation layer. The separator functions as a mirror that reflects at least a part of light having an oscillation wavelength generated from the surface emitting semiconductor laser portion at an interface between the first separation layer and the second separation layer.

In the optical element, the surface emitting semiconductor laser portion may include a second mirror, an active layer formed superjacent to the second mirror, and a first mirror formed superjacent to the active layer. A refractive index of a lowest layer of the second mirror may be different from a refractive index of an uppermost layer of the separator.

### BRIEF DESCRIPTION OF THE DRAWINGS

The invention will be described with reference to the accompanying drawings, wherein like numbers reference like elements.

FIG. 1 is a plan view schematically illustrating an optical element according to an embodiment of the invention.

FIG. 2 is a sectional view schematically illustrating the optical element according to the embodiment of the invention.

FIG. 3 is a sectional view schematically illustrating the optical element according to the embodiment of the invention.

FIG. 4 is a sectional view schematically illustrating a manufacturing process of the optical element according to the embodiment of the invention.

FIG. 5 is a sectional view schematically illustrating a manufacturing process of the optical element according to the embodiment of the invention.

FIG. 6 is an energy band diagram of the main part of the optical element of the embodiment.

FIG. 7 is an energy band diagram of the main part of an optical element of a comparative example.

FIG. 8 is a plan view schematically illustrating an optical element according to a first modification.

FIG. 9 is a plan view schematically illustrating the optical element according to the first modification.

FIG. 10 is a sectional view schematically illustrating the optical element according to the first modification.

FIG. 11 is an energy band diagram of the main part of the optical element of the first modification.

FIG. 12 is a sectional view schematically illustrating an optical element according to a second modification.

### DESCRIPTION OF EXEMPLARY EMBODIMENTS

Embodiments of the invention will now be described with reference to the accompanying drawings.

1. Optical Element

First, an optical element according to an embodiment of the invention will be described.

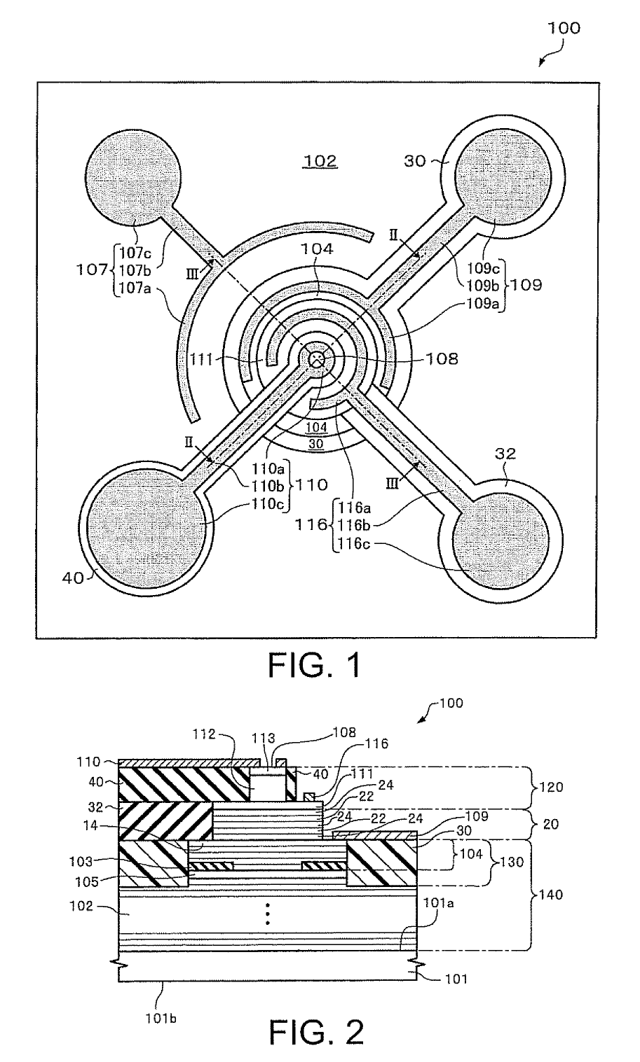

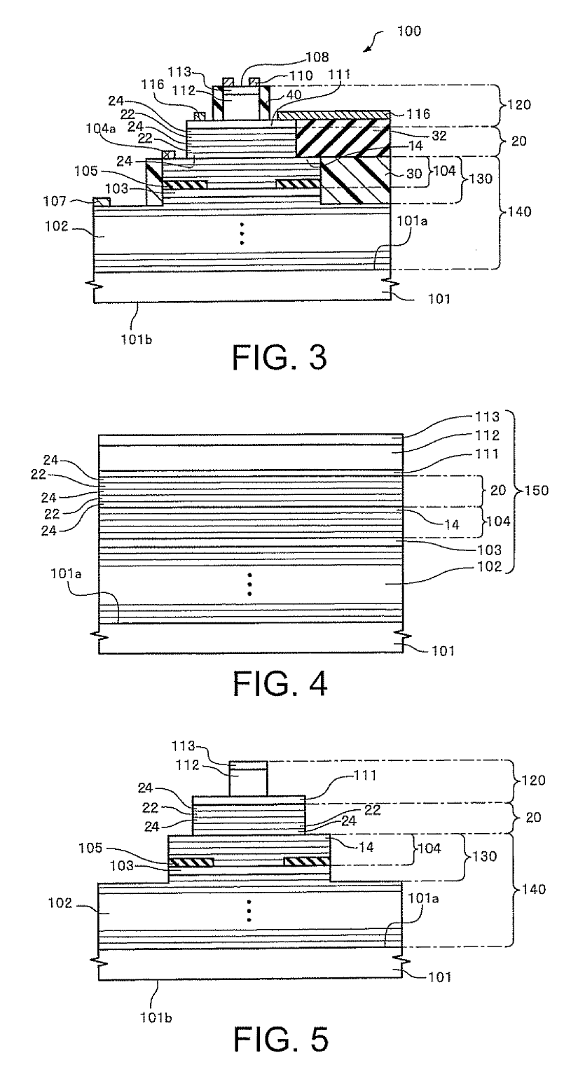

FIG. 1 is a plan view schematically illustrating an optical element 100. FIG. 2 is a sectional view taken along the line II-II of FIG. 1. FIG. 3 is a sectional view taken along the line III-III of FIG. 1.

The optical element 100 of the first embodiment of the invention can include, as shown in FIGS. 2 and 3, a substrate 101, a surface emitting semiconductor laser portion 140, separator 20, a light detector 120, a first electrode 107, a second electrode 109, a third electrode 116, a fourth electrode 110, a first insulation layer 30, a second insulation layer 32, and a third insulation layer 40.

As the substrate 101, a first conductive type (e.g., an n-type) GaAs substrate can be used, for example.

The surface emitting semiconductor laser portion 140 is formed on the substrate 101. The surface emitting semiconductor laser 140 includes a first mirror 102 of a first conductive type (n-type), an active layer 103 formed on the first mirror 102, and a second mirror 104 of a second conductive type (e.g., a p-type) formed on the active layer 103. Specifically, the first mirror 102 is a distribution Bragg reflector (DBR) type mirror composed of alternately layered 40 pairs of an n-type Al_{0.9} Ga_{0.1} As layer and an n-type Al_{0.15} Ga_{0.85} As layer, for example. The active layer 103 has a multiple quantum well (MQW) including three layered quantum well structures each of which is composed of a GaAs well layer and an Al_{0.3} Ga_{0.7} As barrier layer, for example. The second mirror 104 includes the DBR mirror composed of alternately layered 10 pairs of a p-type Al_{0.9} Ga_{0.1} As layer and a p-type Al_{0.15} Ga_{0.85} As layer, and a GaAs layer 14 (the uppermost layer of the second mirror 104) of the p-type, for example. The first mirror 102, the active layer 103, and the second mirror 104 may be a vertical resonator. The composition of each layer and the number of layers included in the first mirror 102, the active layer 103, and the second mirror 104 are not particularly limited. The second mirror 104 of the p-type, the active layer 103 containing no doped impurities, and the first mirror 102 of the n-type constitute a pin diode. A part of the first mirror 102, the active layer 103, and the second mirror 104 can constitute a semiconductor deposited body (herein after, referred to as a “columnar portion”) 130 having a pillar shape, for example. The columnar portion 130 has a circular plan shape, for example.

In addition, as shown in FIGS. 2 and 3, at least one layer of layers included in the second mirror 104 can be made as a current constricting layer 105, for example. The current constricting layer 105 is formed at a region adjacent to the active layer 103. As the current constricting layer 105, an oxidized AlGaAs layer can be used, for example. The current constricting layer 105 is an insulation layer having an opening. The current constricting layer 105 is formed in a ring shape.

The first electrode 107 is formed on the upper surface of the first mirror 102. The first electrode 107 is electrically coupled with the first mirror 102. The first electrode 107 can include a contact 107a, a lead 107b, and a pad 107c, as shown in FIG. 1. The first electrode 107 makes contact with the first mirror 102 with the contact 107a. The contact 107a has a plan shape of, for example, an incomplete ring shape, i.e., a part of the ring is lacked, as shown in FIG. 1. The lead 107b connects the contact 107a and the pad 107c. The lead 107b has a plan shape of, for example, a line as shown in FIG. 1. The pad 107c is coupled with external wirings or the like as an electrode pad. The pad 107c has a plan shape of, for example, a circle as shown in FIG. 1. The first electrode 107 is composed of layered films. For example, a chromium (Cr) film, a gold (Au) and germanium (Ge) alloy film, a nickel (Ni) film, and a gold (Au) film are layered in this order. While the first electrode 107 is formed on the first mirror 102, as shown in FIG. 3, the first electrode 107 may be formed on a back side 101b of the substrate 101.

The second electrode 109 is formed on the second mirror 104 and the first insulation layer 30. The second electrode 109 is electrically coupled with the second mirror 104. The second electrode 109 can include a contact 109a, a lead 109b, and a pad 109c, as shown in FIG. 1. The second electrode 109 makes contact with the second mirror 104 with the contact 109a. The contact 109a has a plan shape of, for example, an incomplete ring shape, i.e., a part of the ring is lacked, as shown in FIG. 1. The lead 109b connects the contact 109a and the pad 109c. The lead 109b has a plan shape of, for example, a line as shown in FIG. 1. The pad 109c is coupled with external wirings or the like as an electrode pad. The pad 109c has a plan shape of, for example, a circle as shown in FIG. 1. The second electrode 109 is composed of layered films. For example, a chromium (Cr) film, a gold (Au) and zinc (Zn) alloy film, and a gold (Au) film are layered in this order.

The first insulation layer 30 is formed on the first mirror 102. The first insulation layer 30 is formed so as to surround the columnar portion 130. The first insulation layer 30 has the lead 109b and the pad 109c formed on its upper surface. The first insulation layer 30 can electrically separate the second electrode 109 and the first mirror 102. As the first insulation layer 30, one can be used that is easily formed in a thicker film as compared with the second insulation layer 32 and the third insulation layer 40. For example, a resin layer made of a polyimide resin, an acrylic resin, an epoxy resin, or the like can be used as the first insulation layer 30.

The separator 20 is formed on the surface emitting semiconductor laser portion 140. The separator 20 is formed by alternately layering a first separation layer 22 and a second separation layer 24. The first separation layer 22 is a layer of a first conductive type while the second separation layer 24 is a layer of a second conductive type different from the first conductive type. Each of the first separation layer 22 and the second separation layer 24 is made of a material having a different refractive index from each other. The separator 20 functions as a mirror, as a whole. As a result, the separator 20 can function as the upper DBR mirror of the surface emitting semiconductor laser portion 140 together with the second mirror 104. That is, the first separation layer 22 is an AlₓGa₁₋ₓAs layer of the first conductive type while the second separation layer 24 is an Al_{y}Ga_{1-y}As layer of the second conductive type. Here, x is different from y. If the first conductive type is the n-type and the second conductive type is the p-type, it is preferable that y is greater than x. The separator 20 can be a mirror composed of alternately layered 15 pairs of an n-type Al_{0.13} Ga_{0.88} As layer serving as the first separation layer 22 and the p-type Al_{0.9} Ga_{0.1} As layer serving as the second separation layer 24, for example.

The separator 20 is composed of a plurality of the first separation layers 22 and the second separation layers 24. The number of layers composed of each of the separation layers 22 and 24 is preferably larger than the number of layers composed of each layer of the second mirror 104. This structure shortens the distance between the active layer 103 and the uppermost layer 14, serving as a contact layer, of the second mirror 104. As a result, a low-resistance structure can be achieved. The number of layers included in each layer is not limited to ones described above.

The Al composition of the uppermost layer 14 of the second mirror 104 is preferably different from that of the first separation layer 24 formed directly on the uppermost layer 14. As a result, the second mirror 104 and the under surface of the separator 20 can function as a mirror. Specifically, in a case where the uppermost layer 14 of the second mirror 104 is made of a p-type GaAs layer (or a p-type Al_{0.12} Ga_{0.88} As layer) having a low Al composition, it is preferable that the second separation layer 24 formed directly on the uppermost layer 14 is made of the p-type Al_{0.9} Ga_{0.1} As layer having a high Al composition.

If a first contact layer 111 is made of AlGaAs (or GaAs), the Al composition of the second separation layer 24 formed directly below the contact layer 111 can be increased than that of the first contact layer 111. The first separation layer 22, the second separation layer 24, and the first contact layer 111 can constitute a semiconductor deposited body (columnar portion) having a pillar shape, for example. The columnar portion has a circular plan shape, for example.

The second insulation layer 32 is formed on the second mirror 104 and the first insulation layer 30. The second insulation layer 32 is formed so as to make contact with a part of the side surface of the columnar portion constituted by the separator 20 and the first contact layer 111. The second insulation layer 32 has a lead 116b and a pad 116c of the third electrode 116, both of which are formed on its upper surface. The second insulation layer 32 can electrically separate the third electrode 116 and the second mirror 104. As the second insulation layer 32, one can be used that is easily fine processed as compared with the first insulation layer 30. For example, as the second insulation layer 32, an inorganic dielectric layer made of silicon oxide, silicon nitride, or the like can be used.

The light detector 120 is formed on the separator 20. The light detector 120 can monitor a light output generated in the surface emitting semiconductor laser portion 140, for example. The light detector 120 includes the first contact layer 111, a light absorption layer 112 formed on the first contact layer 111, and a second contact layer 113 formed on the light absorption layer 112. Specifically, the first contact layer 111 is an n-type GaAs layer, for example. The light absorption layer 112 is a GaAs layer containing no doped impurities, for example. The second contact layer 113 is a p-type GaAs layer, for example. The second contact layer 113 of the p-type, the light absorption layer 112 containing no doped impurities, and the first contact layer 111 of the n-type constitute a pin diode. The second contact layer 113 and the light absorption layer 112 can constitute a semiconductor deposited body (columnar portion) having a pillar shape, for example. The columnar portion has a circular plan shape, for example.

The third electrode 116 is formed on the first contact layer 111 and the second insulation layer 32. The third electrode 116 is electrically coupled with the first contact layer 111. The third electrode 116 can include a contact 116a, the lead 116b, and the pad 116c, as shown in FIG. 1. The third electrode 116 makes contact with the first contact layer 111 with the contact 116a. The contact 116a has a plan shape of, for example, an incomplete ring shape, i.e., a part of the ring is lacked, as shown in FIG. 1. The lead 116b connects the contact 116a and the pad 116c. The lead 116b has a plan shape of, for example, a line as shown in FIG. 1. The pad 116c is coupled with external wirings or the like as an electrode pad. The pad 116c has a plan shape of, for example, a circle as shown in FIG. 1. The third electrode 116 can be made of the same material of the first electrode 107, for example.

The fourth electrode 110 is formed on the second contact layer 113 and the third insulation layer 40. The fourth electrode 110 is electrically coupled with the second contact layer 113. The fourth electrode 110 can include a contact 110a, a lead 110b, and a pad 110c, as shown in FIG. 1. The fourth electrode 110 makes contact with the second contact layer 113 with the contact 110a. The contact 110a has a plan shape of, for example, an incomplete ring shape, i.e., a part of the ring is lacked, as shown in FIG. 1. The contact 110a has an opening on the second contact layer 113. The opening forms a region, in which the contact 110a is not provided, on the upper surface of the second contact layer 113. This region serves as an emitting surface 108 of a laser beam, for example. The emitting surface 108 has a shape of, for example, a circle as shown in FIG. 1. The lead 110b connects the contact 110a and the pad 110c. The lead 110b has a plan shape oft for example, a line as shown in FIG. 1. The pad 110c is coupled with external wirings or the like as an electrode pad. The pad 110c has a plan shape of, for example, a circle as shown in FIG. 1. The fourth electrode 110 can be made of the same material of the second electrode 109, for example.

The first electrode 107, the second electrode 109, the third electrode 116, and the fourth electrode 110 are electrically independent from each other. Because of this structure, the surface emitting semiconductor laser portion 140 and the light detector 120 can be driven independently. That is, the surface emitting semiconductor laser portion 140 can be driven by using the first electrode 107 and the second electrode 109 while the light detector 120 can be driven by using the third electrode 116 and the fourth electrode 110.

The third insulation layer 40 is formed on the first contact layer 111 and the second insulation layer 32. The third insulation layer 40 is formed so as to surround the columnar portion constituted by the light absorption layer 112 and the second contact layer 113. The third insulation layer 40 has the lead 110b and the pad 110c of the fourth electrode 110, both of which are formed on its upper surface. The third insulation layer 40 can electrically separate the fourth electrode 110 and the first contact layer 111. As the third insulation layer 40, one can be used that is easily fine processed as compared with the first insulation layer 30. For example, as the third insulation layer 40, an inorganic dielectric layer made of silicon oxide, silicon nitride, or the like can be used.

2. A Method for Manufacturing an Optical Element

An example of a method for manufacturing the optical element 100 according to the embodiment will now be explained with reference to the drawings.

FIGS. 4 and 5 are sectional views schematically illustrating a manufacturing process of the optical element 100, shown in FIGS. 1 to 3, of the embodiment. Each sectional view corresponds to the sectional view shown in FIG. 2.

(1) First, an n-type GaAs substrate is prepared for the substrate 101, for example, as shown in FIG. 4. Next, a semiconductor multilayered film 150 is formed on the substrate 101 by epitaxial growth while varying the composition. The semiconductor multilayered film 150 is composed of layered semiconductor layers included in the first mirror 102, the active layer 103, the second mirror 104, the first separation layers 22, the second separation layers 24, the first contact layer 111, the optical absorption layer 112 and the second contact layer 113, that are layered in this order. As for the impurity doped in each semiconductor layer, the same impurity (e.g., carbon) can be used for the p-type semiconductor layers while another same impurity (e.g., silicon) can be used for the n-type semiconductor layers, for example. In growing the second mirror 104, at least one layer adjacent to the active layer 103 may be formed so as to serve as the current constricting layer 105 by later oxidization. The layer to be served as the current constricting layer 105 is preferably used with the following conditions. For example, in a case where the first separation layer 22 and the second separation layer 24 are made of AlGaAs, an AlGaAs layer (or AlAs layer) that contains an Al composition higher than that of the first separation layer 22 and the second separation layer 24 is used. In other words, the Al composition of the first separation layer 22 and the second separation layer 24 is preferably lower than that of the AlGaAs layer to be served as the current constricting layer 105. As a result, the separator 20 can be protected from being oxidized in an oxidizing step to form the current constricting layer 105, which will be later described. For example, the Al composition of the first separation layer 22 and the second separation layer 24 is preferably less than 0.95 while that of the AlGaAs layer to be served as the current constricting layer 105 is preferably 0.95 or more.

(2) Next, as shown in FIG. 5, the semiconductor multilayered film 150 is patterned to form the first mirror 102, the active layer 103, the second mirror 104, the first separation layer 22, the second separation layer 24, the first contact layer 111, the light absorption layer 112, and the second contact layer 113 in respective desired shapes. As a result, each columnar portion is formed. The semiconductor multilayered film 150 can be patterned by photolithography or etching, for example. In patterning the first contact layer 111 of the semiconductor multilayered film 150, the second separation layer 24 provided under the first contact layer 111 can function as an etching stopper layer, for example. In patterning the first separation layer 22 and the second separation layer 24 of the semiconductor multilayered film 150, the uppermost layer 14, provided under the first separation layer 22, of the second mirror 104 can function as an etching stopper layer, for example.

Then, the substrate 101, on which each columnar portion has been formed in above step, is put into a steam atmosphere having a temperature of about 400 degrees centigrade to form the current constricting layer 105 by oxidizing the side surface of the layer to be served as the current constricting layer 105, for example.

(3) Next, as shown in FIGS. 2 and 3, the first insulation layer 30 is formed on the first mirror 102 so as to surround the columnar portion 130. First, an insulation layer made of a polyimide resin or the like is formed on the entire surface by using a spin coat method, for example. Then, the upper surface of the columnar portion 130 is exposed by using an etch-back method, for example. Next, the insulation layer is patterned by photolithography and etching, for example. As a result, the first insulation layer 30 can be formed in a desired shape

Then, as shown in FIGS. 2 and 3, the second insulation layer 32 is formed on the second mirror 104 and the first insulation layer 30. First, an insulation layer made of silicon oxide or the like is formed on the entire surface by using a plasma CVD method, for example. Next, the insulation layer is patterned by photolithography and etching, for example. As a result, the second insulation layer 32 can be formed in a desired shape. Performing a fine patterning to form the second insulation layer 32 is easily conducted than that to form the first insulation layer 30.

Then, as shown in FIGS. 2 and 3, the third insulation layer 40 is formed on the first contact layer 111 and the second insulation layer 32. First, an insulation layer made of silicon oxide or the like is formed on the entire surface by using a plasma CVD method, for example. Next, the insulation layer is patterned by photolithography and etching, for example. As a result, the third insulation layer 40 can be formed in a desired shape. Performing a fine patterning to form the third insulation layer 40 is easily conducted than that to form the first insulation layer 30.

The same material, e.g., a polyimide resin, can be used for the first insulation layer 30, the second insulation layer 32, and the third insulation layer 40. In this case, these insulation layers can be formed in one step. After the insulation layers are formed, the columnar portion 130, the surface of the first contact layer 111, and the surface of the second contact layer 113 can be simultaneously exposed by using an etch-back method, for example.

Then, the first electrode 107, the second electrode 109, the third electrode 116, and the fourth electrode 110 are formed. These electrodes can be formed in respective desired shapes by a combination of a vapor deposition method and a lift-off method, for example. It is noted that the order of forming each electrode is not particularly limited.

(4) Through the above steps, the optical element 100 of the embodiment is formed as shown in FIGS. 1 to 3.

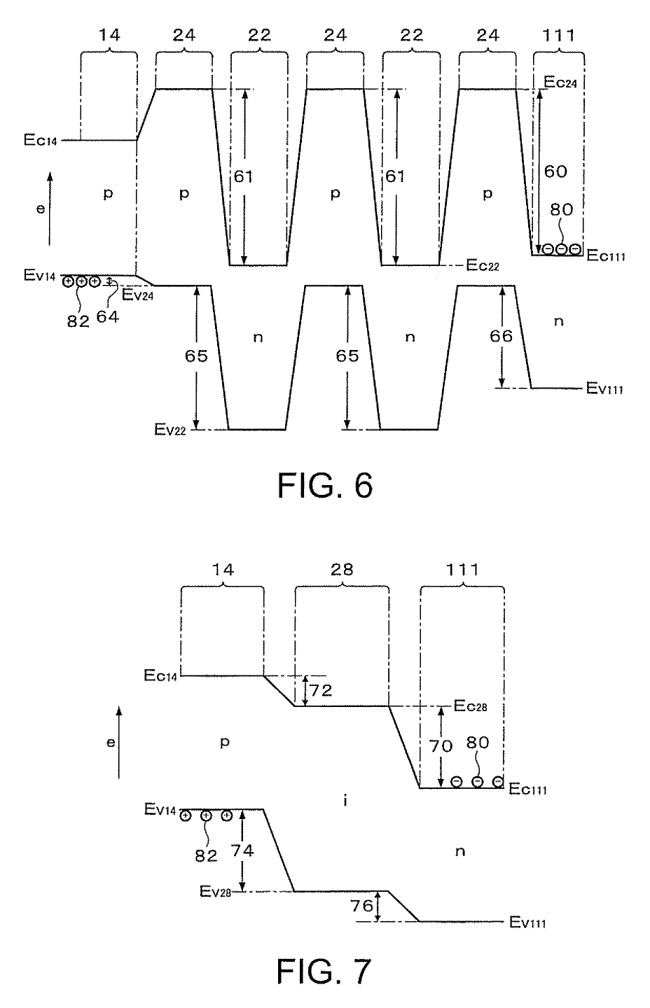

3. The optical element 100 of the embodiment includes the first separation layer 22, which is the first conductive type (e.g., n-type), and the second separation layer 24, which is the second conductive type (e.g., p-type). FIG. 6 shows an example of an energy band diagram of the main part of the optical element 100 of the embodiment. Here, the arrow e shows the direction in which electron energy increases.

In the optical element 100 of the embodiment, an energy Ec₂₄ at the lower end of the conduction band of the second separation layer 24 is higher than an energy Ec₁₁₁ at the lower end of the conduction band of the first contact layer 111, as shown in FIG. 6. An energy Ec₂₂ at the lower end of the conduction band of the first separation layer 22 is lower than an energy Ec₂₄ at the conduction band of the second separation layer 24. An energy Ec₁₄ at the lower end of the conduction band of the uppermost layer 14 of the second mirror 104 is lower than the energy Ec₂₄ at the lower end of the conduction band of the second separation layer 24.

As a result, in the optical element 100 of the embodiment, electrons 80, the major carrier of the first contact layer 111 of the n-type overcome potential barriers 60 and 61 to move to the uppermost layer 14 of the second mirror 104. That is, the first potential barrier 60 formed between the first contact layer 111 and the second separation layer 24, and the second potential barrier 61 formed between the first separation layer 22 and the second separation layer 24 exist against the electrons 80 of the first contact layer 111. The second potential barrier 61 exists in a plurality of numbers. The electrons 80 overcome the plurality of second potential barriers 61.

FIG. 7 shows an energy band diagram in a case where only a separation layer 28 is disposed between the first contact layer 111 and the uppermost layer 14 of the second mirror 104. The separation layer 28 is made of an intrinsic semiconductor (e.g., Al_{0.9} Ga_{0.1} As having no doped impurities). Hereinafter, this case is referred to as a comparative example. In the comparative case, the electrons 80 of the first contact layer 111 also overcome potential barriers 70 and 72 to move to the uppermost layer 14 of the second mirror 104. Here, the summation of the heights of the potential barriers 60 and 61 in the embodiment is higher than that of the potential barriers 70 and 72 in the comparative case, as shown in FIGS. 6 and 7. This relationship is expressed by formula 1 where n is the number of first separation layer 22 and n+1 is the number of second separation layers 24.

|Ec₁₄−Ec₁₁₁|<|Ec₂₄−Ec₁₁₁|+n|Ec₂₄−Ec₂₂| Formula 1

Here, the summation of the heights of the potential barriers 70 and 72 in the comparative example is equal to the difference of the energy Ec₁₄ at the lower end of the conduction band of the uppermost layer 14 of the second mirror 104 and the energy Ec₁₁₁ at the lower end of the conduction band of the first contact layer 111. |Ec₂₄−Ec₁₁₁| represents the height of the first potential barrier 60. |Ec₂₄−Ec₂₂| represents the height of the second potential barrier 61.

In the optical element 100 of the embodiment, satisfying the formula 1, electrons hardly move to the uppermost layer 14 of the second mirror 104 from the first contact layer 111 as compared with the comparative example. Thus, a leak current between the surface emitting semiconductor laser portion 140 and the light detector 120 can be reduced. As a result, the reliability of the optical element 100 can be improved.

In the optical element 100 of the embodiment, the second separation layer 24 is made of Al_{0.9} Ga_{0.1} As of the p-type, having a high Al composition. This structure allows each height of the potential barriers 60 and 61 to be higher as compared with a case where an AlGaAs layer of the p-type having a low Al composition is used. As a result, the summation of the potential barriers 60 and 61 in the embodiment can be more increased.

In the optical element 100 of the embodiment, an energy Ev₂₄ at the upper end of the valence band of the second separation layer 24 is lower than an energy Ev₁₄ at the upper end of the valence band of the uppermost layer 14 of the second mirror 104, as shown in FIG. 6. The energy Ev₂₄ at the upper end of the valence band of the second separation layer 24 is higher than an energy Ev₂₂ at the upper end of the valence band of the first separation layer 22. An energy Ev₁₁₁ at the upper end of the valence band of the first contact layer 111 is lower than the energy Ev₂₄ at the upper end of the valence band of the second separation layer 24.

As a result, in the optical element 100 of the embodiment, holes 82, the major carrier of the uppermost layer 14 of the second mirror 104 of the n-type overcome potential barriers 64, 65, and 66 to move to the first contact layer 111, as shown in FIG. 6. That is, the third potential barrier 64 formed between the uppermost layer 14 of the second mirror 104 and the second separation layer 24, a plurality of fourth potential barriers 65 formed between the second separation layer 24 and the first separation layer 22, and the fifth potential barrier 66 formed between the second separation layer 24 and the first contact layer 111 exist against the holes 82 of the uppermost layer 14 of the second mirror 104.

In the comparative case, the holes 82 of the uppermost layer 14 of the second mirror 104 also overcome potential barriers 74 and 76 to move to the first contact layer 111, as shown in FIG. 7. Here, the summation of the heights of the potential barriers 64, 65 and 66 in the embodiment is higher than that of the potential barriers 74 and 76 in the comparative case, as shown in FIGS. 6 and 7. This relationship is expressed by formula 2 where n is the number of first separation layer 22 and n+1 is the number of second separation layers 24.

|Ev₁₄−Ev₁₁₁|<|Ev₁₄−Ev₂₄|+n|Ev₂₄−Ev₂₂|+|Ev₂₄−Ev₁₁₁| Formula 2

Here, the summation of the heights of the potential barriers 74 and 76 in the comparative example is equal to the difference of the energy Ev₁₄ at the upper end of the valence band of the uppermost layer 14 of the second mirror 104 and the energy Ev₁₁₁ at the upper end of the valence band of the first contact layer 111. |Ev₁₄−Ev₂₄| represents the height of the third potential barrier 64. |Ev₂₄−Ev₂₂| represents the height of the fourth potential barrier 65. |Ev₂₄−Ev₁₁₁| represents the height of the fifth potential barrier 66.

In the optical element 100 of the embodiment, satisfying the formula 2, holes hardly move to the first contact layer 111 from the uppermost layer 14 of the second mirror 104 as compared with the comparative example. Thus, a leak current between the surface emitting semiconductor laser portion 140 and the light detector 120 can be reduced. As a result, the reliability of the optical element 100 can be improved.

In the optical element 100 of the embodiment, the first separation layer 22 can be made of Al_{0.12} Ga_{0.88} As of the n-type and the first contact layer 111 can be made of n-type GaAs layer. This structure allows the energy Ev₂₂ at the upper end of the valence band of the first separation layer 22 to be lower than the energy Ev₁₁₁ at the upper end of the valence band of the first contact layer 111. In addition, the second separation layer 24 made of Al_{0.9} Ga_{0.1} As of the p-type is formed between the first separation layers 22. This structure increases the height of the fourth potential barrier 65. As a result, the summation of the height of the potential barriers 64, 65, and 66 of the embodiment can be more increased.

In the embodiment, the separator 20 can be protected from being oxidized in an oxidizing step to form the current constricting layer 105. Since the separator 20 is not oxidized, it can be prevented from the deterioration of strength and refractive index due to the oxidization.

4. Modifications

Next, modifications of the optical element of the embodiment will now be described. Hereinafter, the feature points of the modifications will be mainly described. Descriptions of other points will be omitted. In addition, the same numeral is given to the part having the same function of that in above-described embodiment.

(1) First Modification

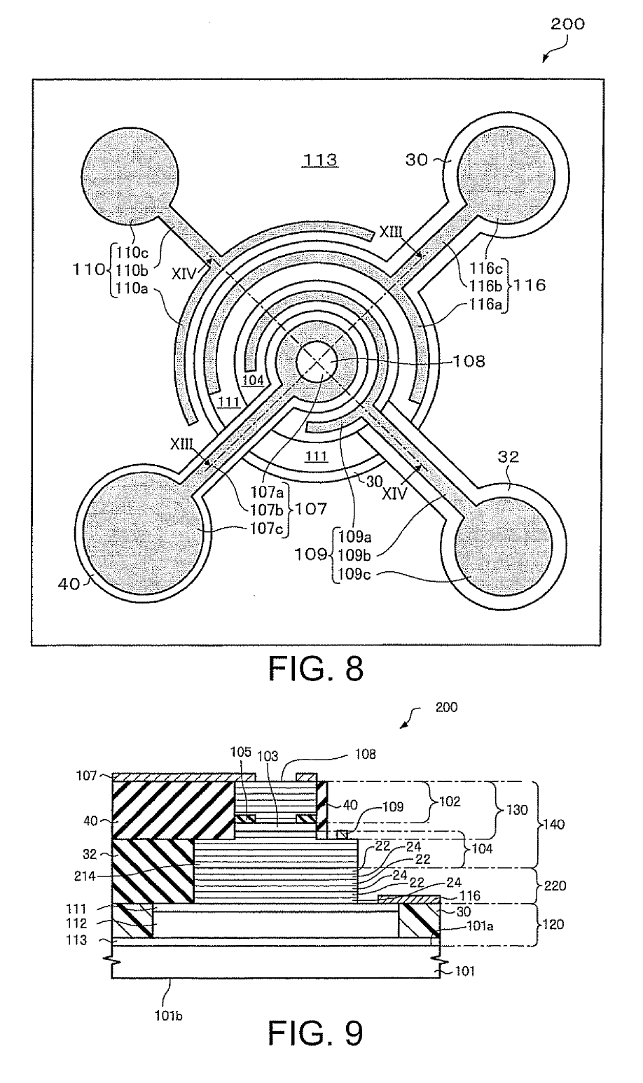

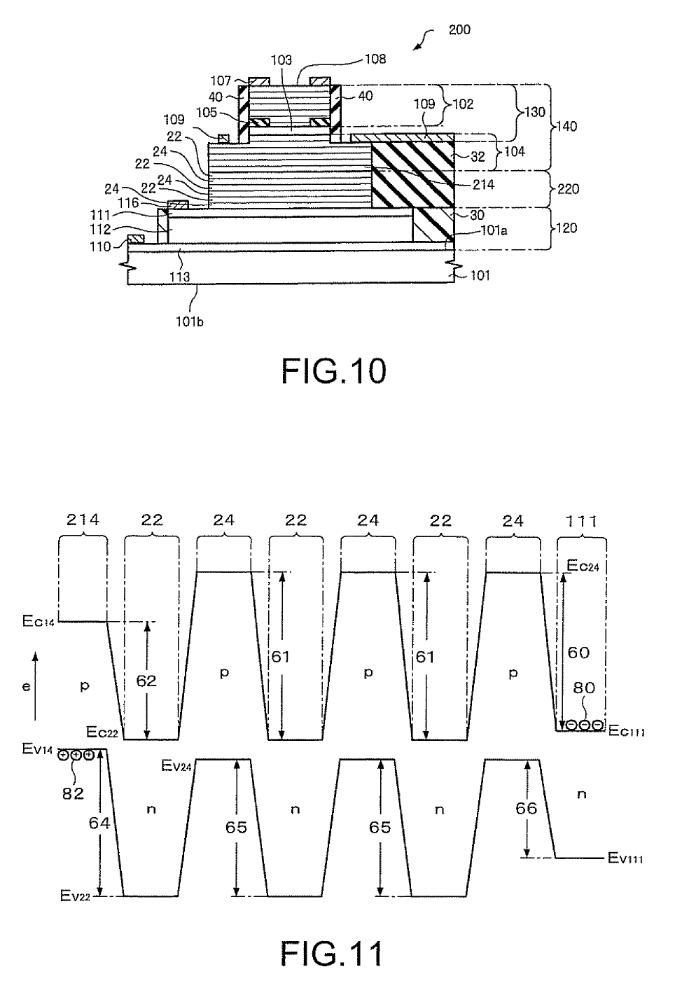

FIG. 8 is a plan view schematically illustrating an optical element 200 of a first modification. FIG. 9 is a sectional view taken along the line XIII-XIII of FIG. 8. FIG. 10 is a sectional view taken along the line XIV-XIV of FIG. 8.

The optical element 200 of the first modification, the light detector 120, the separator 20, and the surface emitting semiconductor laser portion 140 can be layered on the substrate 101 in this order, for example, as shown in FIGS. 9 and 10 while the surface emitting semiconductor laser portion 140, the separator 20, and the light detector 120 are layered on the substrate 101 in this order in the optical element 100.

In the first modification, the first insulation layer 30 is formed on the second contact layer 113, the second insulation layer 32 is formed on the first insulation layer 30 and the first contact layer 111, and the third insulation layer 40 is formed on the second insulation layer 32 and the second mirror 104, for example, as shown in FIGS. 9 and 10. In the modification, at least one layer of layers included in the first mirror 102 can be served as the current constricting layer 105 as shown in FIG. 9.

In the first modification, it is also preferable that the Al composition of the uppermost layer of the separator 20 is a low composition when the Al composition of a lowest layer 214 of the second mirror 104 is a high composition while the Al composition of the uppermost layer of the separator 20 is a high composition when the Al composition of the lowest layer 214 of the second mirror 104 is a low composition. Specifically, in a case where the lowest layer 214 of the second mirror 104 is made of an Al_{0.9} Ga_{0.1} As layer of the p-type having a high Al composition, the first separation layer 22, the uppermost layer of the separator 20, is preferably made of an Al_{0.12} Ga_{0.88} As layer of the n-type having a low Al composition. As a result, a pn-hetero junction is formed to provide a potential barrier since the lowest layer 214 of the second mirror 104 and the uppermost layer of the separator 20 differ in a conductive type.

Likewise, in a case where the first contact layer 111 is made of an n-type GaAs layer having a low Al composition, for example, the second separation layer 24, the lowest layer of the separator 20, is preferably made of the Al_{0.9} Ga_{0.1} As layer of the p-type having a high Al composition.

FIG. 11 shows an example of an energy band diagram of the main part of the optical element 200 of the first modification. In the optical element 200 of the first modification, a sixth potential barrier 62 exists in addition to the first potential barrier 60 and the second potential barrier 61 since the lowest layer 214 of the second mirror 104 and the uppermost layer of the separator 20 differ in a conductive type as described above. This structure can increase the summation of the potential barriers 60, 61, and 62. In addition, the third potential barrier 64 can be heighten since the lowest layer 214 of the second mirror 104 and the uppermost layer of the separator 20 differ in a conductive type. As a result, the summation of the height of the potential barriers 64, 65, and 66 can be increased. Thus, a leak current between the surface emitting semiconductor laser portion 140 and the light detector 120 can be reduced. As a result, the reliability of the optical element 200 can be improved.

(2) Second Modification

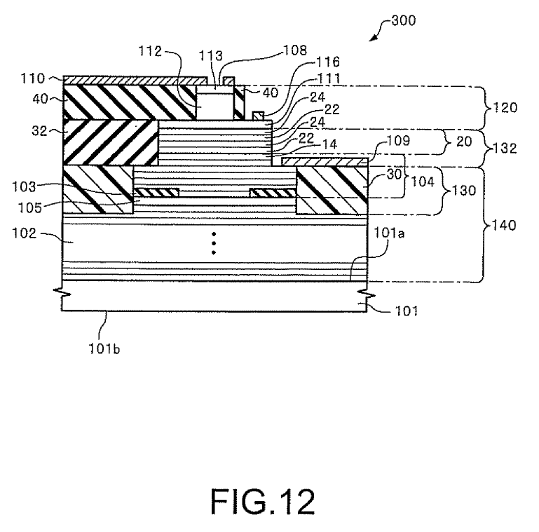

FIG. 12 is a sectional view schematically illustrating an optical element 300 of a second modification, and corresponds to FIG. 2. The optical element 300 of the second modification differs from the optical element 100 in that the upper portion of the second mirror 104 forms a columnar portion 132 formed by the separator 20. Specifically, as shown in FIG. 12, the columnar portion 132 is composed of the upper portion of the second mirror 104 and the separator 20.

The columnar portion 132 is formed by the following steps in the manufacturing process. The separator 20 is over etched to a region of the second mirror 104 while a layer capable of making an ohmic contact with included in the second mirror 104 functions as an etching stopper. By over etching the separator 20, the upper surface of the second mirror 104 can be surely exposed, reliably making contact with an electrode. As a result, the reliability can be improved.

5. Above modifications are only exemplified. Other modifications can be made. For example, each modification can be combined. The p-type and the n-type are interchangeable. An intrinsic semiconductor layer (i-layer) may be formed between the separation layers. The first separation layer or the second separation layer may be made of an intrinsic semiconductor layer having no doped impurities. The upper most layer and lowest layer of the separator 20 may have the same conductive type or a different type from each other. Each of the upper layer and the lowest layer of the separator 20 may or may not form a pn-junction with each of the first contact layer and the uppermost layer of the second mirror. It is not necessarily that each layer included in the mirror of the surface emitting semiconductor laser 140 and each layer included in the separator 20 have the same Al composition. For example, the mirror of the surface emitting semiconductor laser 140 may be composed of an Al_{0.12} Ga_{0.88} As layer and an Al_{0.9} Ga_{0.1} As layer while the separator may be composed of an Al_{0.1} Ga_{0.9} As layer and an Al_{0.88} Ga_{0.12} As layer. In addition, the substrate 101 can be cut off when an epitaxial lift off method is used, for example. That is, it is possible that the optical element 100 doesn't have the substrate 101.

As understood by those skilled in the art, various changes can be made with the embodiment of the invention that has been described in detail without departing from the spirit and scope of the invention. Therefore, it is to be noted that these modifications are all included in the scope of the invention.

What is claimed is:

1. An optical element, comprising:
a surface emitting semiconductor laser portion;
a separator formed superjacent to the surface emitting semiconductor laser portion; and
a light detector formed superjacent to the separator, wherein the separator electrically separates the surface emitting semiconductor laser portion and the light detector, has a first separation layer made of a first conductive type semiconductor and a second separation layer that is formed one of superjacent to and lower the first separation layer and is made of a second conductive type semiconductor having a refractive index different from a refractive index of the first separation layer, and functions as a mirror that reflects at least a part of light having an oscillation wavelength generated from the surface emitting semiconductor laser portion at an interface between the first separation layer and the second separation layer.

2. The optical element according to claim 1, wherein the separator includes the first separation layer and the second separation layer in a plurality of numbers and the first separation layer and the second separation layer are layered alternately.

3. The optical element according to claim 1, wherein the surface emitting semiconductor laser portion includes a first mirror, an active layer formed superjacent to the first mirror, and a second mirror formed superjacent to the active layer, and a refractive index of an uppermost layer of the second mirror is different from a refractive index of a lowest layer of the separator.

4. The optical element according to claim 1, wherein the surface emitting semiconductor laser portion includes a first mirror, an active layer formed superjacent to the first mirror, and a second mirror formed superjacent to the active layer, and the second mirror is a layered body in which a first refractive index layer having a first refractive index and a second refractive index layer having a second refractive index are alternately layered, and the number of layers composed of the first separation layer and the second separation layer in the separator is larger than the number of layers composed of the first refractive index layer and the second refractive index layer.

5. The optical element according to claim 1, wherein the separator is a semiconductor mirror made of a first conductive type AlₓGa₁₋ₓAs layer and a second conductive type Al_{y}Ga_{1-y}As layer that are alternately layered, and x is different from y.

6. The optical element according to claim 5, wherein the separator is a semiconductor mirror made of a p-type AlₓGa₁₋ₓAs layer and an n-type Al_{y}Ga_{1-y}As layer that are alternately layered, and x is larger than y.

7. The optical element according to claim 5, wherein the first conductive type AlₓGa₁₋ₓAs layer is formed as a lowest layer in the separator, and an uppermost layer of the second mirror is made of one of a first conductive type Al_{z}Ga_{1-z}As layer and a second conductive type Al_{z}Ga_{1-z}As layer, and z is smaller than x.

8. The optical element according to claim 1, wherein the surface emitting semiconductor laser portion includes a first mirror, an active layer formed superjacent to the first mirror, a second mirror formed superjacent to the active layer, a first electrode electrically coupled with the first mirror, and a second electrode electrically coupled with the second mirror, and the light detector includes a first contact layer formed superjacent to the separator, a light absorption layer formed superjacent to the first contact layer, a second contact layer formed superjacent to the light absorption layer, a third electrode electrically coupled with the first contact layer, and a fourth electrode electrically coupled with the second contact layer, and the first electrode, the second electrode, the third electrode, and the fourth electrode are electrically independent from each other.

9. An optical element, comprising:
a light detector;
a separator formed superjacent to the light detector;
a surface emitting semiconductor laser portion formed superjacent to the separator, wherein the surface emitting semiconductor laser portion emits laser light upwardly and oscillates light in a downward direction, and the light detector detects the light oscillated from the surface emitting semiconductor laser portion, and the separator electrically separates the surface emitting semiconductor laser portion and the light detector, has a first separation layer made of a first conductive type semiconductor and a second separation layer that is formed one of superjacent to and under the first separation layer and is made of a second conductive type semiconductor having a refractive index different from a refractive index of the first separation layer, and functions as a mirror that reflects at least a part of light having an oscillation wavelength generated from the surface emitting semiconductor laser portion at an interface between the first separation layer and the second separation layer.

10. The optical element according to claim 9, wherein the surface emitting semiconductor laser portion includes a second mirror, an active layer formed superjacent to the second mirror, and a first mirror formed superjacent to the active layer, and a refractive index of a lowest layer of the second mirror is different from a refractive index of an uppermost layer of the separator.
